(19) United States
(12) Patent Application Publication
(10) Pub. No.: US 2016/0128187 A1
(43) Pub. Date: May 5, 2016

(54) FLEXIBLE AND TRANSPARENT ELECTRODE AND MANUFACTURING METHOD THEREOF

(71) Applicant: National Taiwan University, Taipei (TW)

(72) Inventors: Guey-Sheng LIOU, Taipei (TW); Heng-Yi LU, Taipei (TW); Chin-Yen CHOU, Taipei (TW); Jiang-Jen LIN, Taipei (TW)

(21) Appl. No.: 14/598,901

(22) Filed: Jan. 16, 2015

(30) Foreign Application Priority Data
Oct. 30, 2014 (TW) 103137583

(51) Int. Cl. H05K 1/03; H05K 3/00; B29C 39/36; H05K 3/22; B29C 39/12; H05K 1/09; H05K 3/46

(52) U.S. Cl. CPC H05K 1/0393; H05K 1/0326; H05K 1/09; H05K 3/0014; H05K 3/007; H05K 3/4682; H05K 3/227; B29C 39/123; B29C 39/36; H05K 2201/015; H05K 2201/0154; H05K 2201/0326; H05K 2203/1105; H05K 2203/125; H05K 2203/122; H05K 2203/1305; B29K 2079/08

(57) ABSTRACT

The present invention relates to a flexible and transparent electrode and manufacturing method thereof. The flexible transparent electrode comprises an insoluble polyimide film as a substrate and metal nanowires as a conductor, wherein the insoluble polyimide film is polymerized by aromatic diamines and alicyclic diamines of thermal imidization. In addition, the coating method of polyimides of the present invention not only improves the adhesion and dispersion between metal nanowires and substrate, but also exhibits good thermal stability; moreover, the transparent electrode keeps the effectiveness even in high temperature processing conditions such as annealing, laser, plasma or other severe operation environment. Using the step transfer printing method can produces the transparent electrode product with smooth surfaces, thermo stability, and organic solvent resistance, so as to improve the adhesion of metal nanowires and lower the resistance of the transparent electrode.

### BACKGROUND OF THE INVENTION

1. Technical Field

The present invention relates to a flexible transparent electrode and method for preparing the same, especially relates to a flexible transparent electrode using an organo-insoluble polyimide (PI) film as a substrate and a metal nanowire as a conductive layer.

2. Description of Related Art

With advances in technology, the products of computers, communications and consumer electronics sprang up like mushrooms over the last two decades. The advances in materials are essential to enhance the performance of both high conductivity and transmittance. This important research topic has attracted great attention by using carbon nanotube (CNTs), graphene, metal oxide, and metallic nanowires. Though indium tin oxide (ITO) has excellent properties in both electricity and optics, there are some serious problems faced with ITO, such as high cost of indium and brittle property of ITO, and thus promotes scientists to research on new materials.

Thus, some strategies adopted to obtain new hybrid materials for preparing flexible and transparent electrodes. For example, CNTs have been studied since 1991, and the electrodes made by CNTs showed sheet resistance of 200Ω sq⁻¹ and transmittance of 80% at 550 nm. However, such performances were still hard to achieve commercial requirements. Another member of carbon family, graphene, also attracted a lot of attention since the discovery of graphene awarded the Nobel Prize of physics in 2010. Nevertheless, single layer and few layers graphene, that satisfy the requirements of transparent conductive electrodes, could only be prepared by chemical vapor deposition method (CVD). However, the CVD method requires very high temperature and vacuum degree, and additional process of transferring is necessary for CVD graphene. Therefore, the metal nanowires have been considered as the most potential candidate to replace the ITO in the future. The most widely used method for generating metal nanowires was template-directed synthesis. However, this method was characterized with problems such as irregular morphology, low aspect ratio, and low yield. Until 2002, a scientist group first proposed a polyol process to produce silver nanowires (AgNWs) as a simple and large scale way, which used poly(vinylpyrrolidone) (PVP) as capping agent and ethylene glycol (EG) as reductant to reduce the silver nitrate. In order to obtain transparent electrodes from AgNWs, a great deal efforts on the development of synthesis, coating methods, and annealing process of AgNWs have been laid. Some applications of the transparent conductive electrodes obtained from AgNWs have been reported such as solar cells, touch screen, heater, and light-emitting diodes. In addition, the transparent electrodes derived from AgNWs also have potential to be applied as transparent electrochromic devices (ECD) and memory devices.

### BRIEF SUMMARY OF THE INVENTION

One major problem in the development of AgNWs is poor adhesion property between substrate, and yet solutions to the problem are now available. For example, some research teams use a poly(ethylene oxide) or conductive poly (3,4-ethylenedioxythiophene): poly(styrene-sulfonate) as a nanowires binder and protector. While the aforesaid conductive polymer is effective in enhancing adherence and electrical performance of AgNWs, it has low thermal stability and a pale blue color, both of which are disadvantageous to optical applications.

To solve the issues stated above, it is an objective of the present invention to provide a flexible transparent electrode which includes an organo-insoluble polyimide (PI) film serving as a substrate and metal nanowires serving as a conductive layer. The organo-insoluble PI film is formed by imidization of an aromatic dianhydride, a fluorine-contained diamine, and an alicyclic diamine.

Preferably, the fluorine-contained diamine and the alicyclic diamine in the organo-insoluble PI film are in a ratio of 8:2.

Preferably, the metal nanowires are formed of a metal selected from the group consisting of silver, gold, copper, nickel, and titanium.

Preferably, the conductive layer is formed on the substrate by the metal nanowires via a solution coating process.

Preferably, the conductive layer is formed on the substrate by the metal nanowires via a transferring process.

Another embodiment of the present invention is to provide a method for preparing the flexible transparent electrode, comprising the steps of: (a) preparing a poly(amic acid) from the aromatic dianhydride, the fluorine-contained diamine, and the alicyclic diamine; (b) coating a poly(amic acid) on a base material, drying in vauo, and performing thermal imidization process to obtain a organo-insoluble PI film served as a substrate on the base material; (c) providing a metal nanowire hybird solution which mix with an organo-soluble PI solution; (d) coating the metal nanowires/organo-soluble PI hybrid solution on a organo-insoluble PI substrate prepared in step (b), drying in vacuo, and forming a conductive layer on the substrate surface; and (e) peeling the coated film from base material. The flexible and transparent conducive film is obtained.

Preferably, the organo-soluble PI solution is prepared from an alicyclic dianhydride and a fluorine-contained diamine.

Preferably, the heating temperature in step (b) is about 275° C.

Preferably, the heating temperature in step (d) is about 200° C.

Another embodiment of the present invention is to provide a method for preparing the flexible transparent electrode, comprising the steps of: (a) preparing a poly(amic acid) from the aromatic dianhydride, the fluorine-contained diamine, and the alicyclic diamine; (b) providing a base material, coating a metal nanowires solution, and drying in vacuo to obtained a conductive layer; (c) coating a poly(amic acid) prepared in step (a) onto the conductive layer obtained in step (b), drying in vacuo, and performing thermal imidization process to obtain a organo-insoluble PI film served as a binder on the base material; (d) coating the organo-soluble PI as a substrate material onto the imidized organo-insoluble layer prepared in step (c); (e) peeling three layers which coated in step (b), (c), and (d) from the base material. The conductive layer (metal nanowire networks) is transfer onto the organo-insoluble PI which also lay on the organo-soluble PI substrate material.

Preferably, the heating temperature in step (c) is about 275° C.

According to the present invention, the flexible transparent electrode can be prepared by a coating process in which organo-soluble PI is used as a binder and protector to protect the metal nanowires from peeling off easily. Moreover, the PIs used in this process have no adverse effect on the transmittance of the electrode. In addition, the PIs used in this preparation method exhibit high glass transition temperature (T_{g}) more than 325° C. and high 5 wt % decomposition temperature more than 450° C. Thus, these optically transparent of metal nanowires/PI hybrid electrodes have extremely high potential to operate at high temperature working environment such as plasma, laser, or annealing process.

According to the present invention, the foregoing flexible transparent electrode can also be prepared by a transferring process, which provides the following advantages. First, highly smooth surface of conductive layer is appropriate for precise device processing. Second, the organo-insoluble PI layer as metal nanowire protector not only exhibits excellent thermal stability, but also prevents the metal nanowires from removing by external force and the presence of some organic solvent. Third, the rapid preparation is conducted by simultaneous annealing and imidization step. Fourth, the conductivity of transparent electrode could be improved by the gravity compaction during the coating process of PIs

### BRIEF DESCRIPTION OF THE SEVERAL VIEWS OF THE DRAWINGS

FIG. 1 (a) Schematic diagram for fabrication procedure of transparent AgNWs/PI transparent electrodes. Two kinds of PI were used as binder and substrate respectively. (b) SEM image of AgNWs at 60 degree tilted. (c) TEM image of AgNWs. (d) UV-Vis transmittance spectra of prepared electrodes with various amount of AgNWs coated on glass. (e) Amount of AgNWs plotted with sheet resistance values of AgNWs/PI coated on glass.

FIG. 2. (a) The ITO coated PEN (ITO-PEN) lost the conductivity after folding. Therefore, the LED lamps no longer emitted any light. (b) The AgNWs/PI electrode connected with LED array which lamps kept working even on folding. (c) The resistance variation of ITO-PEN after bending for 10 times. The Y-axis represented the change of resistance divided by original resistance. (d) The resistance variation of AgNWs/PI electrodes after bending cycles for 1000 times.

FIG. 3. Peeling off test of (a) pristine AgNWs electrode and (b) AgNWs/PI electrode by 3M scotch tapes. The SEM is adopted to observe the morphology of AgNWs networks after peeling off test.

FIG. 4. (a) The defogging device made by AgNWs/PI electrode was put in refrigerator and then given an applied potential of 6 V. The water on the surface was removed after one minute. (b) The temperature plotted with time at various applied potential. (c) The electrochromic behavior of electrochromic device (ECD), which used AgNWs/PI electrode as cathode and ITO glass as anode. (d) Cyclic voltammetric diagram of ECD based on AgNWs/PI electrode for 30 cycles.

FIG. 5. Schematic diagram for fabrication procedure of AgNWs/PI electrodes by transferring method.

### DETAILED DESCRIPTION OF THE INVENTION

As used in the description herein and throughout the claims that follow, the meaning of “a,” “an,” and ‘the” includes plural reference unless the context clearly dictates otherwise. Also, as used in the description herein and throughout the claims that follow, the meaning of “in” includes “in” and “on” unless the context clearly dictates otherwise. Moreover, titles or subtitles may be used in the specification for the convenience for a reader, which shall have no influence on the scope of the present invention. Additionally, some terms used in the specification are more specifically defined below.

[The Transparent Electrode of the Present Invention]

The primary objective of the present invention is to provide a flexible transparent electrode which includes an organo-insoluble PI film and metal nanowires, wherein the organo-insoluble PI film served as a substrate and the metal nanowires served as a conductive layer. The organo-insoluble PI film is formed by imidization of an aromatic dianhydride, a fluorine-contained diamine, and an alicyclic diamine poly(amic acid).

The aforesaid organo-insoluble PI is suitable for serving as the substrate because it is insoluble in water or common organic solvents. In addition, the coefficient of thermal expansion (CTE) of organo-insoluble PI is about 8 ppm/° C., which is as small as glass (7.1 ppm/° C. for common glass).

The organo-insoluble PI film adopted in the flexible transparent electrode can be formed by imidization of a known aromatic dianhydride, a known fluorine-contained diamine, and a known alicyclic diamine, as disclosed in Macromolecules 2007, 40, 3527-3529 and High Performance Polymers, 15: 47-64, 2003. Preferably, the ratio between the fluorine-contained diamine and the alicyclic diamine in the organo-insoluble PI film is, but not limited to, 8:2. The ratio of 8:2 is preferred in preparing the substrate of the transparent electrode because an organo-insoluble PI composed in such a ratio exhibits a relatively small coefficient of thermal expansion and relatively high thermal stability.

The metal nanowires adopted in the flexible transparent electrode are selected preferably but not necessarily from the group consisting of silver, gold, copper, nickel, or titanium. The metal nanowires are preferably AgNWs in this case. AgNWs prepared by modified polyol process showed high average aspect ratio of 300 with the diameter ranging from 90 to 110 nm and length ranging from 10 to 50 μm. The greater the aspect ratio, the more transparent and the more electrically conductive of the resulting electrode will be.

The conductive layer of the flexible transparent electrode can be formed on the substrate by the metal nanowires via a coating process such as casting, transferring process, or the like.

[Method for Preparing the Flexible Transparent Electrode via a Coating Process of the Present Invention]

The present invention further provides a method for preparing the flexible transparent electrode comprising the steps of: (a) preparing a poly(amic acid) from the aromatic dianhydride, the fluorine-contained diamine, and the alicyclic diamine; (b) coating a poly(amic acid) on a base material, drying in vauo, and performing thermal imidization process to obtain a organo-insoluble PI film served as a substrate on the base material; (c) providing a metal nanowire hybird solution which mix with an organo-soluble PI solution; (d) coating the metal nanowires/organo-soluble PI hybrid solution on a organo-insoluble PI substrate prepared in step (b), drying in vacuo, and forming a conductive layer on the substrate surface; and (e) peeling the coated film from base material. The flexible and transparent conducive film is obtained.

In an embodiment of the present invention, the chemical reaction in the foregoing step (a) is preferably the one expressed by the following equation (I):

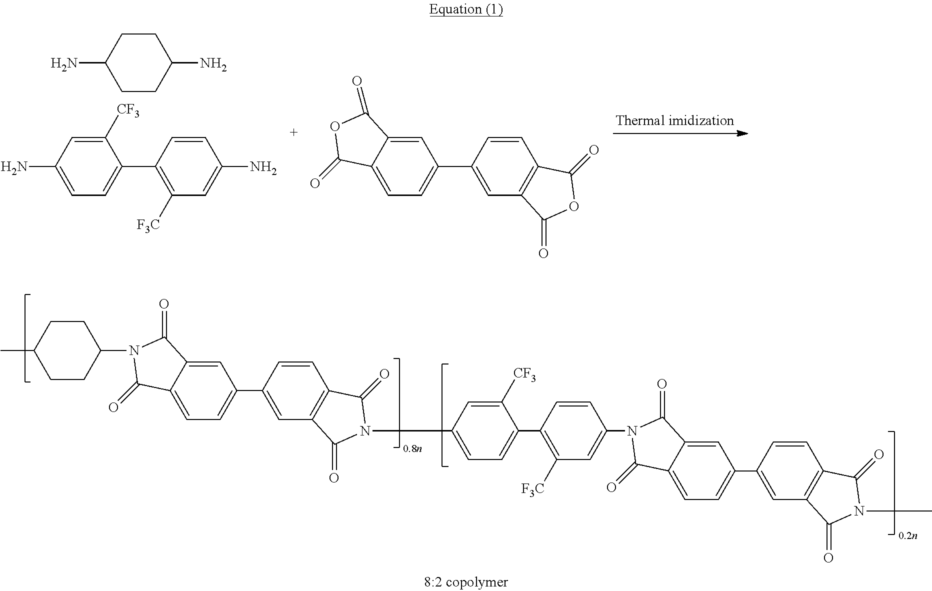

where the ratio between the fluorine-contained diamine and the alicyclic diamine is preferably, but not limited to, 8:2.

Herein, the term “base material” refers to a supporting substance on which the organo-insoluble PI solution is coated and allowed to dry. The base material in the foregoing step (b) can be but is not limited to glass.

In the foregoing step (b), poly(amic acid) is transformed to a solid film by vacuo drying, and then the temperature is increased to 200-300° C. for thermal imidization to obtain organo-insoluble PI film (i.e., the substrate).

In the foregoing step (c), the organo-soluble PI solution is prepared by polymerization, or more specifically by chemical imidization of an alicyclic dianhydride and a fluorine-contained diamine, wherein both the alicyclic dianhydride and the fluorine-contained diamine are known compounds, as disclosed in Journal of Polymer Science, Part A: Polymer Chemistry, 2013, 51, 575-592.

In an embodiment of the present invention, the chemical reaction for preparing the organo-soluble PI can be expressed by the following equation (II):

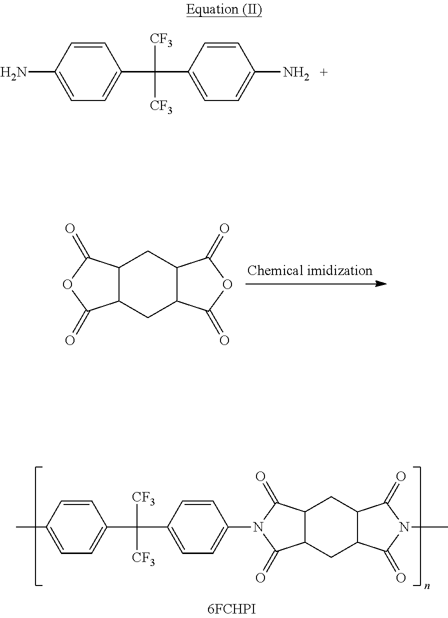

In the foregoing step (c), the metal species adopted in the hybrid solution is preferably selected from the group consisting of silver, gold, copper, nickel, and titanium. Preferably, the metal nanowire solution is a silver nanowire preserved in ethanol, which can be transformed easily to another organic solvent such as dimethylacetamide (DMAc) by a solvent exchange process. More specifically, the silver nanowire preserved in ethanol solution is first concentrated by centrifugation and removed excessive ethanol supernatant. The residue silver nanowire solution then poured into a single-neck flask with an appropriate amount of DMAc mixed. The single-neck flask is connected with a valve adapter, which is connected to a vacuum pump. The single-neck flask is placed on a hotplate and heated to about the boiling point of ethanol under vacuum. Thus, the residue ethanol is removed completely, and a silver nanowire preserved in DMAc solution is obtained. Because of high dissolving power and low boiling point of DMAc, it is adopted suitably in organo-soluble PI and AgNWs hybrid system

The metal nanowires/organo-soluble PI solution mixed solution in the foregoing step (c) can be subjected to thermal gravimetric analysis (TGA) to analyze the percentage of each of its components, with a view to preparing a mixed liquor in which the ratio by weight between the PI binder and the metal nanowires (e.g., AgNWs) is 1:1; that is to say, each ml of the metal nanowire-containing DMAc solution contains 1 mg of metal nanowires and 1 mg of PI binder. The concentration of metal nanowires/organo-soluble PI hybrid solution can be measured by thermal gravimetric analysis (TGA). Thus, the weight percentage of metal nanowires and PI solution is controlled in 1:1; that is to say, 1 mg of metal nanowires and 1 mg of PI would be contained in 1 ml hybrid solution.

In the foregoing step (d), the organo-insoluble PI has been pretreated by immersing poly-L-lysine to enhance surface hydrophilicity and dispersibility of metal nanowires.

In the present invention, the organo-soluble PI solution is used as a binder and protector. More specifically, it is mixed with the metal nanowires and then coated on the substrate to form the conductive layer which is effectively enhanced the adhesion properties of metal nanowires.

In the foregoing step (d), the coated conductive layer is heated to about 200° C. Preferably, the object is heated on a hotplate for about one hour. This heating step can lower the electrical resistance of the metal nanowires because of the removal of polyvinylpyrrolidone (PVP) covered on metal nanowires. In addition, the joint area between the metal nanowire networks also has been enhanced due to the melts in parts of nanowire.

In the method described above, the organo-insoluble PI is offered a substrate that can endure the solution casting of metal nanowires and binder PI hybrid solution.

In the method described above, the organo-soluble PI is used as a binder to keep the metal nanowires from peeling off. In addition, the organo-soluble PI also facilitates the hybrid system for other metal nanowires. Not only that, both the organo-soluble PI and the organo-insoluble PI have glass transition temperatures higher than 325° C. and 5wt % of thermal decomposition temperature in air higher than 450° C. Thus, the polymeric materials could be withstand high temperature annealing process, which is typically carried out at about 200° C.

Moreover, the PIs used in the foregoing method are optically advantageous due to their colorless. By the proper structural design, the charge transfer effect could be depressed to result in the colorless PI. The introduction of high electronegative bulky fluorine atoms or adopting of aliphatic monomers could decrease charge transfer effect. Therefore, transparent, colorless, and soluble PI could be prepared from aliphatic dianhydride and fluorine-containing diamine by chemical imidization, while PI substrate with high chemical resistance was obtained by thermal imidizaiton from fluorine-containing and aliphatic diamine monomers with aromatic dianhydride.

[Method for Preparing the Flexible Transparent Electrode via Transfer Process of the Present Invention]

A method for preparing the flexible transparent electrode, comprising the steps of: (a) preparing a poly(amic acid) from the aromatic dianhydride, the fluorine-contained diamine, and the alicyclic diamine; (b) providing a base material, coating a metal nanowires solution, and drying in vacuo to obtained a conductive layer; (c) coating a poly(amic acid) prepared in step (a) onto the conductive layer obtained in step (b), drying in vacuo, and performing thermal imidization process to obtain a organo-insoluble PI film served as a binder on the base material; (d) coating the organo-soluble PI as a substrate material onto the imidized organo-insoluble layer prepared in step (c); (e) peeling three layers which coated in step (b), (c), and (d) from the base material. The conductive layer (metal nanowire networks) is transfer onto the organo-insoluble PI which also lay on the organo-soluble PI substrate material.

In the foregoing step (a), the aromatic dianhydride, the fluorine-contained diamine, and the alicyclic diamine can be those described above. In the foregoing step (b), the metal nanowires are made of a metal preferably selected from the group consisting of silver, gold, copper, nickel, and titanium. AgNWs are preferably used. Suitable solvent using for metal nanowire solution include water, alcohols (e.g., ethanol, propanol, etc.), ketones (e.g., acetone), toluene, hexane, dimethylformamide, tetrahydrofuran, esters (e.g., ethyl acetate), ethers, hydrocarbons, aromatic solvents (e.g., xylene), propylene glycol methyl ether (PGME), propylene glycol methyl ether acetate (PGMEA), and a combination thereof. Ethanol is preferably used.

In the foregoing step (b), the base material can be but is not limited to glass. Before processing, the base material can be cleaned by ultrasound vibration with acetone and a cleaning agent and dried in oven. Besides, the base material can be immersed in poly-L-lysine for about 30 minutes to modify the surface more hydrophilic, which is helpful in dispersing the metal nanowires.

In the foregoing step (b), the surface of the base material can be coated with the metal nanowire solution by, for example, drop coating, spin coating, or spray coating. The thermal drying process can be performed in a vacuo at about 80-100° C.

In the foregoing step (c) of the method for preparing the flexible electrode, the poly(amic acid) is first dried to form a poly(amic acid) film. Then, thermal imidization is conducted by heating so that the poly(amic acid) film is transformed to an organo-insoluble PI film. The heating temperature is preferably, but not limited to, about 250 to 300° C. and is more preferably 275° C. In this step, heating to high temperature can serve both annealing and thermal imidization simultaneously.

In the foregoing step (d), the organo-insoluble PI film substrate is peeled off from a base material. Because of the difference of adhesion property between PI and metal nanowires (e.g., AgNWs), the metal nanowires served as the conductive layer can be transferred to the PI substrate easily. Consequently, the flexible transparent electrode of the present invention is formed.

The advantages of preparing the flexible transparent electrode by the foregoing transferring process include as following. First, highly smooth surface electrode is appropriate for precise device. Second, the organo-insoluble PI, which served as the protector of metal nanowires, not only exhibits good thermal resistant, but also can prevents the metal nanowires from peeling off in the presence of organic solvent. Third, the annealing and imidization steps are completed simultaneously. Fourth, the conductivity of hybrid electrode could be improved by the gravity compaction during the casting process of PI

Hereinafter, the present disclosure will be specifically described with reference to examples and drawings. However, the present disclosure is not limited to the examples and the drawings.

### ILLUSTRATIVE EMBODIMENTS

### Prepared Example 1

### Transparent and Colorless Organo-Soluble PI (Binder)-6FCHPI

The synthesis of transparent PI 6FCHPI was polymerized by chemical imidization, as shown in the following equation (I). 0.2442 g (1 mmol) of 1,2,4,5-cyclohexane tetracarboxylic dianhydride was added in one portion (30 wt % solid content) into the solution of 0.3343 g (1 mmol) of diamine 4,4′-(hexafluoroisopropylidene)dianiline in 1.4 mL of DMAc at room temperature under nitrogen flow. The mixture was kept stirring at room temperature for about 3 days. The imidization agents, pyridine 0.4 mL and acetic anhydride 0.95 mL were added into the reactor. The imidization process was also done at room temperature for 24 h. The resulting polymer solution was poured into 200 mL of methanol giving a white precipitate and collected by filtration.

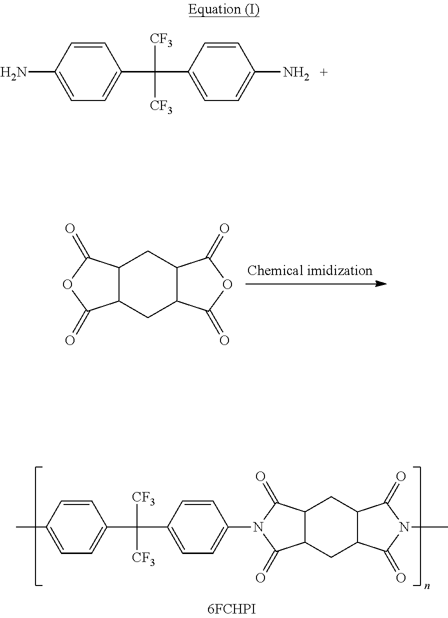

### Prepared Example 2

### Transparent and Colorless Organo-Insoluble PI (Substrate)-8:2 Copolymer

Organo-insoluble colorless PI 8:2 copolymer was prepared by the commercial available diamines trans-1,4-cyclohexanediamine and 2,2′ -bis(trifluoromethyl)benzidine which the molar ratio was 8:2 with 4,4′-biphthalic anhydride via thermal imidization, as shown in the following equation (II).

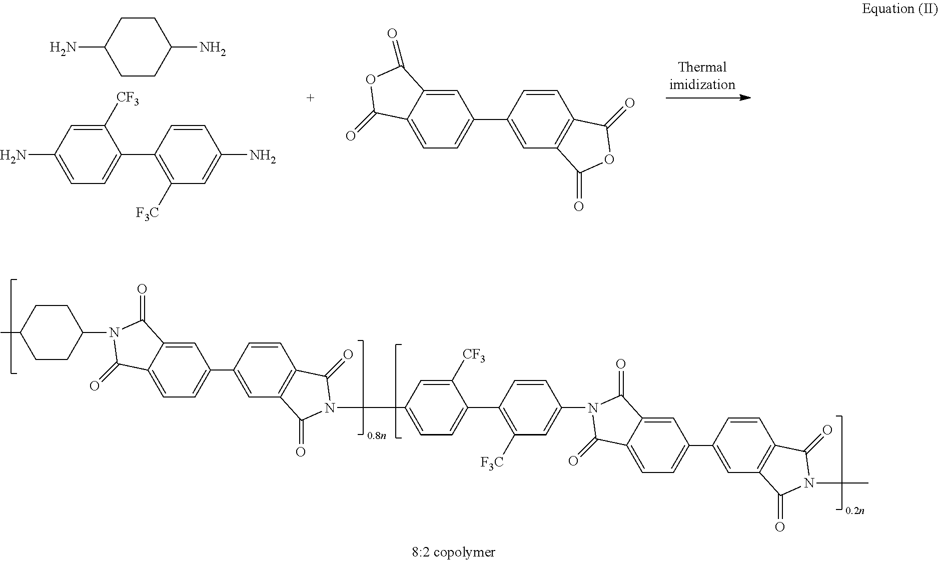

Test of Solubility Behavior of Colorless PIs

The solubility properties of PIs and 6FCHPI were investigated qualitatively. Hexafluoroisopropylidene group in the 6FCHPI is used to increase the free volume of the PI; thereby solubility can be improved. Results are summarized in table as follows.

| | Solubility Behavior of Colorless Polyimides^{a} | | | | | | |
|---|---|---|---|---|---|---|---|
| | | | | | m- | | |
| | NMP | DMAc | DMF | DMSO | Cresol | THF | CHCl₃ |
| 6FCHPI | ++ | ++ | ++ | ++ | + | ++ | +− |
| 8:2 | − | − | − | − | − | − | − |
| Copolymer | | | | | | | |

^{a}++, soluble at room temperature; +, soluble on heating; + −, partially soluble or swelling; −, insoluble even on heating.

Thermal properties of colorless PIs

The organo-soluble PI (binder) was prepared by preparation example-1 and the organo-insoluble PI (substrate) was prepared by preparation example-2. Results are summarized in table as follows.

| | T_{g}^{a} | CTE^{b} | T_{d}^{5 (° C.)}^{c} | | R_{w800}^{d} |
|---|---|---|---|---|---|
| | (° C.) | (ppm/° C.) | N₂ | Air | (%) |
| 6FCHPI | 347 | 81 | 480 | 460 | 22.8 |
| 8:2 Copolymer | 326 | 8 | 490 | 450 | 14.8 |

^{a}Glass transition temperature measured by TMA with a constant applied load of 10 mN at a heating rate of 10° C./min by film/fiber mode in nitrogen;
^{b}The coefficient of linear thermal expansion data were determined by TMA;
^{c}Temperature at which 5% weight loss occurred, recorded by TGA at a heating rate of 20° C./min and a gas flow rate of 20 cm³/min;
^{d}Residual weight percentages at 800° C. under nitrogen, also called as char yield.

As foresaid, colorless PIs have glass transition temperatures (T_{g}) higher than 325° C.

Optical Properties of Colorless PI

The thickness of all the colorless PI films is between 20-30 μm. Results are summarized in table as follows.

| | Color coordinate^{a} | | | T (%)^{b} | | λₒ |
|---|---|---|---|---|---|---|
| | b* | a* | L* | 450 nm | 550 nm | (nm)^{c} |
| 6FCHPI | 0.89 | −0.05 | 94.46 | 90.2 | 90.8 | 276 |
| 8:2 copolymer | 1.91 | −0.19 | 93.94 | 83.8 | 86.1 | 371 |

^{a}The CIE 1976 (L*, a*, b*) color space (or CIELAB);
^{b}Transmittance at 450, and 550 nm measured by U-vis with the thickness of film about 20 μm;
^{c}Cutoff wavelength.

The transmittance of these colorless PIs in the visible region is high, which could be used in the electronic device. The three coordinates of CIELAB represent the lightness of the color (L*=0 yields black and L*=100 indicates diffuse white; specular white may be higher), its position between red/magenta and green (a*, negative values indicate green while positive values indicate magenta) and its position between yellow and blue (b*, negative values indicate blue and positive values indicate yellow). All the color intensities of PI films indicate high L* values (>93), low a* values (approaches 0) and low b* values (approaches 0). The results indicate that the 6FCHPI and 8:2 copolymer are approach to colorless transparent substance.

### Example 1

### Preparing the Flexible Transparent Electrode of the Present Invention by a Coating Process

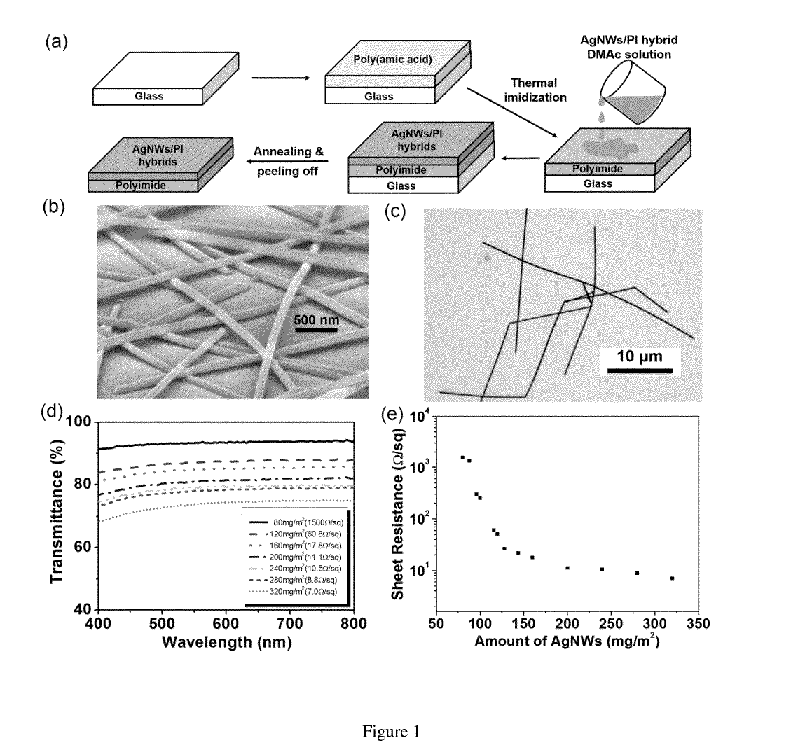

Example 1 is described below with reference to FIG. 1.

FIG. 1(a) shows a procedure to prepare a flexible transparent electrode by a coating process. The colorless organo-soluble PI prepared in preparation example 1 is introduced into a DMAc solution containing AgNWs. Then, the solution is drop-coated onto the colorless organo-insoluble PI substrate prepared in preparation example 2 and the random networks of AgNWs are formed on a piece of base material (i.e., glass) which has been treated with poly-L-lysine beforehand. After that, annealing is conducted to lower the electrical resistance of the silver nanowire/PI electrode. Lastly, the electrode is peeled off from the base material to form the flexible transparent electrode in the present example.

The AgNWs were prepared by modified polyol process that used EG as reductant and solvent, PVP as capping agent, silver nitrate as provider of silver cations, and copper chloride as oxygen scavenger. The synthesized AgNWs showed average diameter of 100 nm and average length of 35 μm. The SEM and TEM image of AgNWs were shown in FIGS. 1(b) and 1(c) respectively. The average aspect ratio of these AgNWs was higher than 350. The aspect ratio was high enough to use as transparent electrodes. By this coating method, high transmittance and low sheet resistance of the film could be reached. UV-Vis spectra of prepared electrodes with various amount of AgNWs coated on glass were shown in FIG. 1(d). While the amount of AgNWs was 80 mg m⁻², the transmittance at 550 nm was 93.4%. Nevertheless, the sheet resistance is too high to be used. Therefore, the amount of AgNWs should be increased to lower the resistance. For electrode of 200 mg m⁻² AgNWs, the transmittance was higher than 80% at 550 nm with sheet resistance of only 11Ω sq⁻¹, which were comparable to the commercial ITO electrode. FIG. 1(e) exhibited the amount of AgNWs plotted with sheet resistance of AgNWs/PI hybrid electrode.

### Experimental Example-1

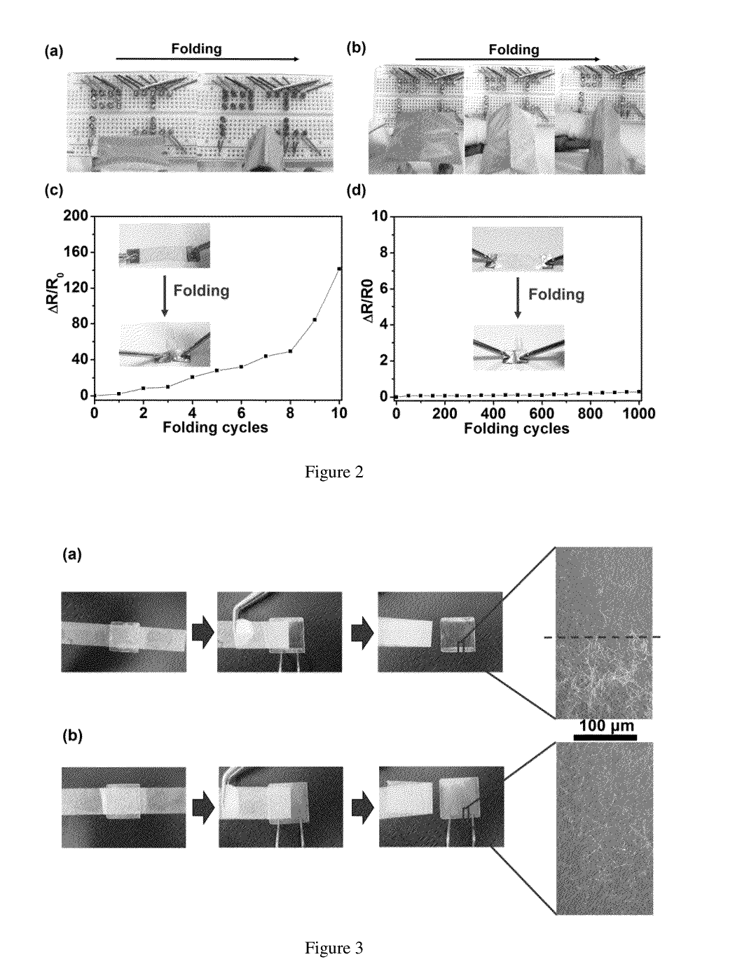

Illustrated the present invention accordance with FIG. 2.

In order to make a comparison, the folding test of commercial ITO coated polyethylene naphthalate (PEN) was shown in FIG. 2(a). ITO-PEN electrode was connected with LED lamps and folded. It lost conductivity while it was folding and the LED no longer worked. Nevertheless, the AgNWs/PI electrode let lamps continue to work even on folding, because the network of nanowires will not be broken down after folding (FIG. 2(b)). To further detailed discussion, the resistance change divided by pristine resistance was recorded after many cycles of folding. FIG. 2(c) showed the resistance change of ITO-PEN, the resistance increased to 140 times of pristine value only for 10 cycles of folding. However, AgNWs/PI electrode exhibited excellent flexibility. There was almost no change of resistance even after folding for 1000 cycles (FIG. 2(d)).

### Experimental Example-2

Illustrated the present invention accordance with FIG. 3.

The peeing off test was done by 3M scotch tape as shown in FIG. 3(a). While pristine AgNWs could be easily peeled off from substrates by 3M scotch tape, the AgNWs with the protection of PI exhibited very strong adhesion to the substrate (FIG. 3(b)).

### Experimental Example-3

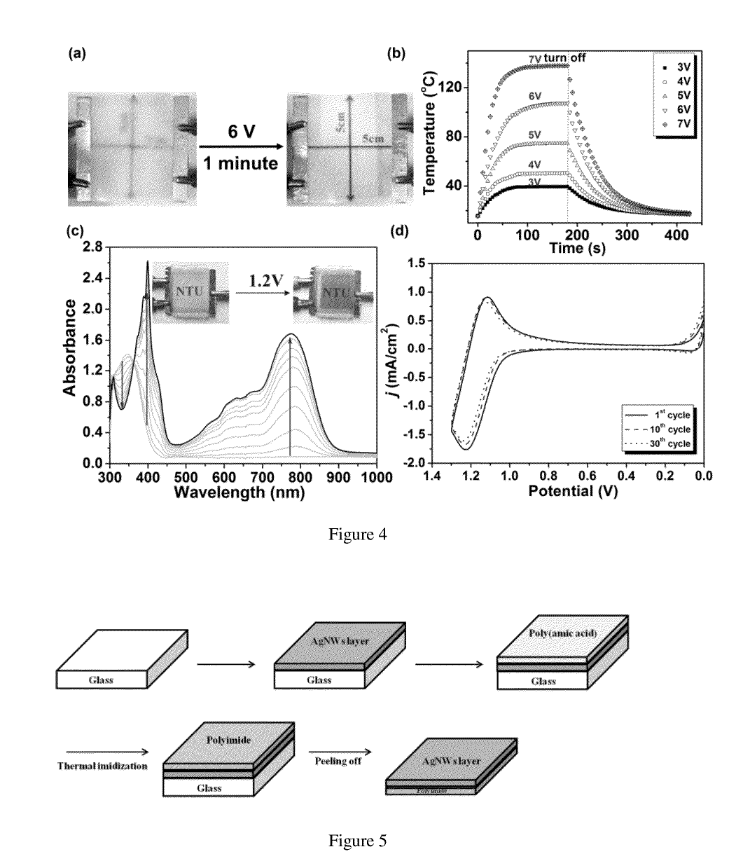

Illustrated the present invention accordance with FIG. 4.

The defogging device made by hybrid electrodes of example 1 of the present invention also showed good performance on producing thermal energy (FIG. 4(a)). The device could remove water within one minute while 6 V of potential was applied. The higher the applied potential the higher the temperature could be reached (FIG. 4(b)). In addition, the AgNWs/PI hybrid electrode could also be applied in electrochromic device (FIG. 4(c)). While 1.2 V was applied, the device changed from colorless to blue-green color. It also exhibited good stability even after scanning for 30 cycles of cyclic voltammetry (FIG. 4(d)).

### Example 2

### Preparing the Flexible Transparent Electrode of the Present Invention by a Transfer Process

Example 2 is described below with reference to FIG. 5.

The steps of preparing the flexible electrode by a transfer process including: preparing a piece of glass as the base material; washing the base material with acetone and a cleaning agent via ultrasonic vibration; drying the washed base material in the oven; immersing the to-be-coated surface of the base material in poly-L-lysine for 30 minutes surface modification; coating the AgNWs/ethanol solution on the glass surface (the AgNWs being prepared in the same way as example 1); drying the coated glass in a vacuum oven at 80° C.; coating the poly(amic acid) (i.e., the precursor of organo-insoluble PI)/DMAc solution prepared in preparation example 2; placing the coated glass in a vacuum oven for drying so that a poly(amic acid) film is formed; increasing the temperature to 275° C. so that a PI film is formed by thermal imidization; coating the organo-soluble PI as a substrate material onto the imidized organo-insoluble layer and then drying in vacuo; and peeling the PI film off from the glass. Owing to a difference adhesion property between PI and base material, the AgNWs will be transferred to the PI film easily; thus, a transparent conductive film is formed.

What is claimed is:

1. A flexible transparent electrode, comprising: an organo-insoluble polyimide film serving as a substrate; and metal nanowires serving as a conductive layer; wherein the organo-insoluble polyimide film is formed by imidization of an aromatic dianhydride, a fluorine-contained diamine, and an alicyclic diamine.

2. The flexible transparent electrode of claim 1, wherein the fluorine-contained diamine and the alicyclic diamine in the organo-insoluble polyimide film, are in a ratio of 8:2.

3. The flexible transparent electrode of claim 1, wherein the metal nanowires are formed of a metal selected from the group consisting of silver, gold, copper, nickel, and titanium.

4. The flexible transparent electrode of claim 1, wherein the conductive layer is formed on the substrate by the metal nanowires via a coating process.

5. The flexible transparent electrode of claim 1, wherein the conductive layer is formed on the substrate by the metal nanowires via a transfer process.

6. A method for preparing the flexible transparent electrode of claim 4, comprising the steps of:
(a) preparing a poly(amic acid) from the aromatic dianhydride, the fluorine-contained diamine, and the alicyclic diamine;
(b) coating a base material with the poly(amic acid), and performing thermal imidization to obtain organo-insoluble polyimide film served as the substrate on the base material;
(c) preparing a hybrid solution, which is mix with metal nanowires solution and an organo-soluble polyimide solution;
(d) coating the substrate with the metal nanowires/organo-soluble polyimide solution;
drying in vacuo; and then heating the metal nanowires/organo-soluble polyimide solution to form a conductive layer on the substrate; and
(e) peeling the substrate and conductive layer from the base material.

7. The method of claim 6, wherein the organo-soluble polyimide solution is prepared from an alicyclic dianhydride and a fluorine-contained diamine.

8. The method of claim 6, wherein the heating in step (d) is heating to about 200° C.

9. A method for preparing the flexible transparent electrode of claim 5, comprising the steps of:
(a) preparing a poly(amic acid) from the aromatic dianhydride, the fluorine-contained diamine, and the alicyclic diamine;
(b) providing a base material, coating a metal nanowires solution, and drying in vacuo to obtained a conductive layer;
(c) coating the poly(amic acid) prepared in step (a) onto the conductive layer obtained in step (b), drying in vacuo, and performing thermal imidization process to obtain a organo-insoluble polyimide film served as a binder on the base material;
(d) coating a organo-soluble polyimide as a substrate material onto the imidized organo-insoluble layer prepared in step (c);
(e) peeling three layers which coated in step (b), (c), and (d) from the base material.

10. The method of claim 9, wherein the heating in step (c) is heating to about 275° C.
